(19) United States
(12) Patent Application Publication
(10) Pub. No.: US 2021/0219442 A1
(43) Pub. Date: Jul. 15, 2021

(54) LIGHT SOURCE MODULE AND ELECTRONIC DEVICE WITH SAME

(71) Applicant: Primax Electronics Ltd., Taipei (TW)

(72) Inventors: Wei-Ping Chan, Taipei (TW); Wei-Chiang Huang, Taipei (TW)

(21) Appl. No.: 17/031,770

(22) Filed: Sep. 24, 2020

Related U.S. Application Data
(60) Provisional application No. 62/959,045, filed on Jan. 9, 2020.

(51) Int. Cl. H05K 5/02; H01L 25/075; H01L 33/60

(52) U.S. Cl. CPC H05K 5/02; H01L 33/60; H01L 25/0753

(57) ABSTRACT

A light source module includes a transparent substrate, a conductive coating film structure and plural light-emitting elements. The conductive coating film structure is installed on the transparent substrate. The conductive coating film structure includes a metal conductive plate and a metal coating film. The metal conductive plate is disposed on the transparent substrate and covered by the metal coating film. The plural light-emitting elements are installed on the conductive coating film structure, and electrically connected with the metal conductive plate. The light-emitting elements are permitted to emit light beams. When the light beams are not emitted by the light-emitting elements, the light-emitting elements are not displayed on the conductive coating film structure according to a mirror reflection effect provided by the metal coating film.

### CROSS-REFERENCE TO RELATED APPLICATION

This application claims priority to U.S. Provisional Patent Application No. 62/959,045 filed Jan. 9, 2020, the contents of which are incorporated herein by reference.

### FIELD OF THE INVENTION

The present invention relates to a light source module, and more particularly to a light source module with plural light-emitting elements.

### BACKGROUND OF THE INVENTION

Recently, electronic devices with slim appearance are favored by users because they are easily carried. In addition to the slim appearance, electronic devices can provide sound and light effects. Consequently, users pay much attention to the electronic devices. For example, a computer host for electronic sports is usually equipped with a light source module. When the light source module is driven to emit plural light beams, the computer host for electronic sports generates a luminous effect. Moreover, the light source module needs to have a slim structure.

The layout structure of a conventional light source module will be described as follows. FIG. 1 schematically illustrates the layout structure of a conventional light source module. As shown in FIG. 1, the light source module 1 comprises a transparent conductive substrate 11 and plural light-emitting elements 12. The transparent conductive substrate 11 comprises a substrate base 111 and a conductive film 112. The conductive film 112 is installed on the substrate base 111. For example, the conductive film 112 is made of indium tin oxide (ITO). Moreover, plural conductor lines 1121 are formed on the conductive film 112. The light-emitting elements 12 are installed on the corresponding conductor lines 1121. The conductive film 112 is connected with a power source through additional wires 13. The light-emitting elements 12 acquire the electric power from the power source through the wires 13 and the conductive film 112. Consequently, the light-emitting elements 12 are enabled to emit light beams.

In addition to the luminous function, users also hope that the appearance of the electronic device can produce different visual effects. For example, when no light beams are emitted by the light source module 1, the plural light-emitting elements 12 are not observed by the naked eyes. Consequently, the visual effect is more aesthetically-pleasing.

Therefore, there is a need of providing a light source module capable of providing special visual effects.

### SUMMARY OF THE INVENTION

An object of the present invention provides a light source module capable of providing special visual effects.

Another object of the present invention provides an electronic device capable of providing special visual effects.

In accordance with an aspect of the present invention, a light source module is provided. The light source module includes a transparent substrate, a conductive coating film structure and at least one light-emitting element. The conductive coating film structure is installed on the transparent substrate. The conductive coating film structure includes a metal conductive plate and a metal coating film. The metal conductive plate is disposed on the transparent substrate and covered by the metal coating film. The metal coating film is permitted to provide a mirror reflection effect. The at least one light-emitting element is installed on the conductive coating film structure, and electrically connected with the metal conductive plate. The at least one light-emitting element is permitted to emit at least one light beam.

In accordance with another aspect of the present invention, an electronic device is provided. The electronic device includes a casing and a light source module. The casing is exposed outside the electronic device. The light source module is installed on the casing. The light source module includes a transparent substrate, a conductive coating film structure and at least one light-emitting element. The conductive coating film structure is installed on the transparent substrate. The conductive coating film structure includes a metal conductive plate and a metal coating film. The metal conductive plate is disposed on the transparent substrate and covered by the metal coating film. The metal coating film is permitted to provide a mirror reflection effect. The at least one light-emitting element is installed on the conductive coating film structure, and electrically connected with the metal conductive plate. The at least one light-emitting element is permitted to emit at least one light beam.

When the at least one light-emitting element emits the at least one light beam, the at least one light-emitting element is displayed on the conductive coating film structure. When the at least one light beam is not emitted by the at least one light-emitting element, the at least one light-emitting element is not displayed on the conductive coating film structure according to the mirror reflection effect.

From the above descriptions, the present invention provides the light source module and the electronic device with the light source module. A conductive coating film structure is installed on a transparent substrate to provide a mirror reflection effect. The conductive coating film structure comprises a metal conductive plate and a metal coating film. The metal coating film is formed on the metal conductive plate. The metal conductive plate and the metal coating film are both made of metallic material. Since the metal conductive plate and the metal coating film are made of the same material, the film forming process of the present invention is easier and the yield is enhanced when compared with the film forming process using the difficult materials. By controlling the thickness of the metal coating film, the resistance value is correspondingly adjusted. Consequently, the appropriate conductive coating film structure can be produced according to the practical requirements. That is, the customized conductive coating film structure can be manufactured.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 schematically illustrates the layout structure of a conventional light source module;

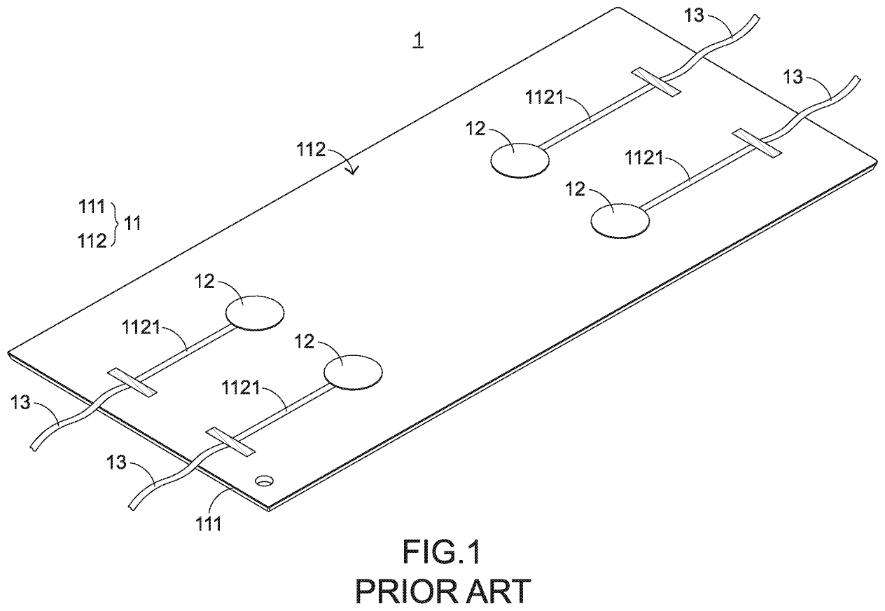

FIG. 2 is a schematic side view illustrating the structure of a light source module according to a first embodiment of the present invention;

FIG. 3 is a schematic perspective view illustrating the appearance of an electronic device with a light source module according to a second embodiment of the present invention; and

FIG. 4 is a schematic perspective view illustrating the appearance of the electronic device of the second embodiment of the present invention, in which a mirror reflection effect is generated.

### DETAILED DESCRIPTION OF THE PREFERRED EMBODIMENT

The present invention provides a light source module and an electronic device in order to overcome the drawbacks of the conventional technologies. The embodiments of present invention will be described more specifically with reference to the following drawings. For well understanding the present invention, the elements shown in the drawings are not in scale with the elements of the practical product. In the following embodiments and drawings, the elements irrelevant to the concepts of the present invention or the elements well known to those skilled in the art are omitted. It is noted that numerous modifications and alterations may be made while retaining the teachings of the invention.

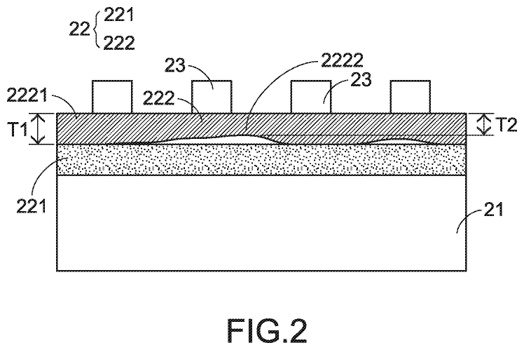

FIG. 2 is a schematic side view illustrating the structure of a light source module according to a first embodiment of the present invention. The light source module 2 comprises a transparent substrate 21, a conductive coating film structure 22 and plural light-emitting elements 23. The conductive coating film structure 22 is installed on the transparent substrate 21. The conductive coating film structure 22 comprises a metal conductive plate 221 and a metal coating film 222. The metal conductive plate 221 is disposed on the transparent substrate 21 and covered by the metal coating film 222. Due to the metallic properties, the metal coating film 222 provides a mirror reflection effect. The plural light-emitting elements 23 are installed on the conductive coating film structure 22 and electrically connected with the metal conductive plate 221. When the plural light-emitting elements 23 are enabled, the plural light-emitting elements 23 emit the corresponding light beams.

In an embodiment, the light-emitting elements 23 are micro light emitting diodes (Micro LEDs) or mini light emitting diodes (Mini LED), and the light-emitting elements 23 are installed on the conductive coating film structure 22 through a surface mount technology (SMT). Moreover, the metal conductive plate 221 is made of aluminum or silver. It is noted that the examples of the light-emitting elements, the method of installing the light-emitting elements on the conductive coating film structure and the material of the metal conductive plate are not restricted.

Please refer to FIG. 2 again. The metal coating film 222 has a first region 2221 and a second region 2222. The first region 2221 has a first thickness T1. The second region 2222 has a second thickness T2. The resistance value corresponding to the first region 2221 is higher than the resistance value corresponding to the second region 2222. Moreover, the first region 2221 can provide more obvious mirror reflection effect than the second region 2222.

When the plural light-emitting elements 23 emit light beams, the light-emitting elements 23 are displayed on the conductive coating film structure 22 according to the optical effect. Meanwhile, the light source module 2 can provide a luminous effect. When no light beams are emitted by the plural light-emitting elements 23, the light-emitting elements 23 are not displayed on the conductive coating film structure 22 according to the mirror reflection effect of the metal coating film 222. Meanwhile, the light source module 2 provides a clean and simple visual effect.

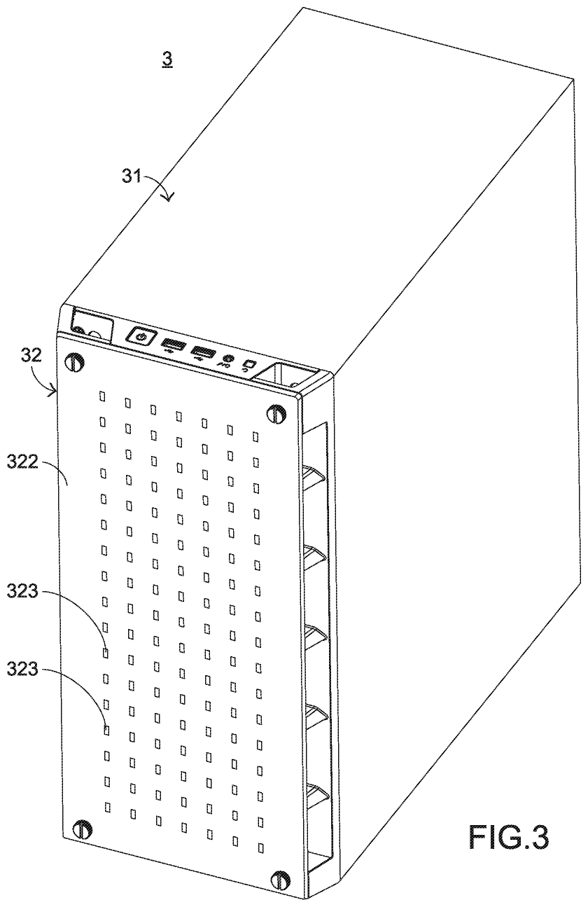

The present invention further provides an electronic device with the above light source module. FIG. 3 is a schematic perspective view illustrating the appearance of an electronic device with a light source module according to a second embodiment of the present invention. The electronic device 3 comprises a casing 31 and a light source module 32. The casing 31 is exposed outside the electronic device 3. The light source module 32 is installed on the casing 31. The light source module 32 comprises a transparent substrate (not shown), a conductive coating film structure 322 and plural light-emitting elements 323. The conductive coating film structure 322 comprises a metal conductive plate (not shown) and a metal coating film (not shown). The structure and the operation of the light source module 32 are similar to those of the first embodiment, and not redundantly described herein.

Please refer to FIG. 3 again. When the plural light-emitting elements 323 emit light beams, the light-emitting elements 323 are displayed on the conductive coating film structure 32 according to the optical effect. Meanwhile, the light source module 3 can provide a luminous effect.

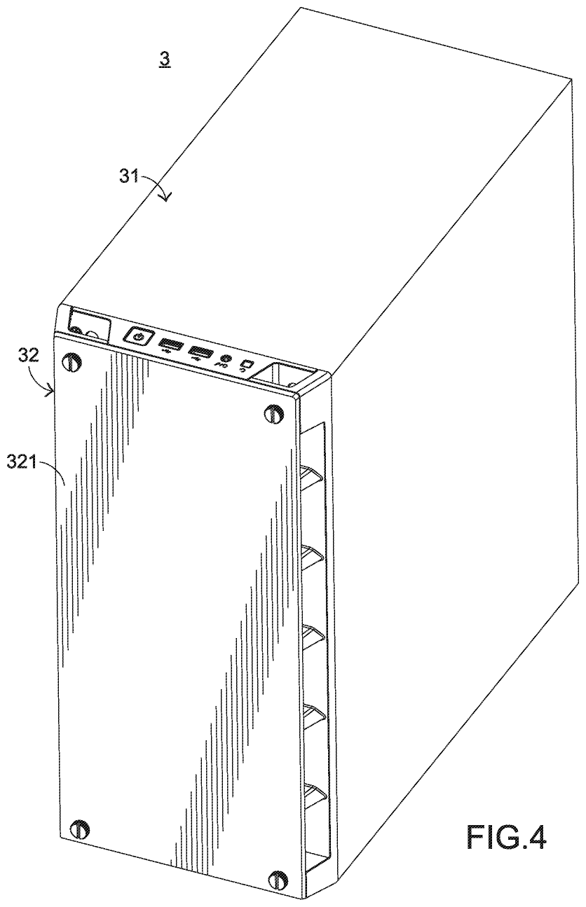

FIG. 4 is a schematic perspective view illustrating the appearance of the electronic device of the second embodiment of the present invention, in which a mirror reflection effect is generated. When no light beams are emitted by the plural light-emitting elements 323, the light-emitting elements 323 are not displayed on the conductive coating film structure 322 according to the mirror reflection effect of the metal coating film 322. Meanwhile, a clean and simple visual effect is provided.

From the above descriptions, the present invention provides the light source module and the electronic device with the light source module. A conductive coating film structure is installed on a transparent substrate to provide a mirror reflection effect. The conductive coating film structure comprises a metal conductive plate and a metal coating film. The metal coating film is formed on the metal conductive plate. The metal conductive plate and the metal coating film are both made of metallic material. Since the metal conductive plate and the metal coating film are made of the same material, the film forming process of the present invention is easier and the yield is enhanced when compared with the film forming process using the difficult materials. By controlling the thickness of the metal coating film, the resistance value is correspondingly adjusted. Consequently, the appropriate conductive coating film structure can be produced according to the practical requirements. That is, the customized conductive coating film structure can be manufactured.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation to encompass all such modifications and similar structures.

What is claimed is:

1. A light source module, comprising:
a transparent substrate;
a conductive coating film structure installed on the transparent substrate, and comprising a metal conductive plate and a metal coating film, wherein the metal conductive plate is disposed on the transparent substrate and covered by the metal coating film, and the metal coating film is permitted to provide a mirror reflection effect; and
at least one light-emitting element installed on the conductive coating film structure, and electrically connected with the metal conductive plate, wherein the at least one light-emitting element is permitted to emit at least one light beam.

2. The light source module according to claim 1, wherein the metal conductive plate is made of aluminum or silver.

3. The light source module according to claim 1, wherein the at least one light-emitting element is installed on the conductive coating film structure through a surface mount technology.

4. The light source module according to claim 1, wherein when the at least one light-emitting element emits the at least one light beam, the at least one light-emitting element is displayed on the conductive coating film structure, wherein when the at least one light beam is not emitted by the at least one light-emitting element, the at least one light-emitting element is not displayed on the conductive coating film structure according to the mirror reflection effect.

5. The light source module according to claim 1, wherein the metal coating film has a first region and a second region, wherein the first region has a first thickness, the second region has a second thickness, and a resistance value corresponding to the first region is higher than a resistance value corresponding to the second region.

6. An electronic device, comprising:
a casing exposed outside the electronic device; and
a light source module installed on the casing, and comprising:
a transparent substrate;
a conductive coating film structure installed on the transparent substrate, and comprising a metal conductive plate and a metal coating film, wherein the metal conductive plate is disposed on the transparent substrate and covered by the metal coating film, and the metal coating film is permitted to provide a mirror reflection effect; and
at least one light-emitting element installed on the conductive coating film structure, and electrically connected with the metal conductive plate, wherein the at least one light-emitting element is permitted to emit at least one light beam.

7. The electronic device according to claim 6, wherein the metal conductive plate is made of aluminum or silver.

8. The electronic device according to claim 6, wherein the at least one light-emitting element is installed on the conductive coating film structure through a surface mount technology.

9. The electronic device according to claim 6, wherein when the at least one light-emitting element emits the at least one light beam, the at least one light-emitting element is displayed on the conductive coating film structure, wherein when the at least one light beam is not emitted by the at least one light-emitting element, the at least one light-emitting element is not displayed on the conductive coating film structure according to the mirror reflection effect.

10. The electronic device according to claim 6, wherein the metal coating film has a first region and a second region, wherein the first region has a first thickness, the second region has a second thickness, and a resistance value corresponding to the first region is higher than a resistance value corresponding to the second region.
